(19) United States
(12) Patent Application Publication
(10) Pub. No.: US 2024/0396359 A1
(43) Pub. Date: Nov. 28, 2024

(54) A NIMH BATTERY CHARGER, AND A CONTROL METHOD OF A NIMH BATTERY CHARGER

(71) Applicant: Nilar International AB, Täby (SE)

(72) Inventor: Jenny AXÉN, Danderyd (SE)

(73) Assignee: Nilar International AB, Täby (SE)

(21) Appl. No.: 18/696,225

(22) PCT Filed: Sep. 29, 2022
(86) PCT No.: PCT/SE2022/050867

§ 371 Date: Mar. 27, 2024

(30) Foreign Application Priority Data
Sep. 30, 2021 (SE) 2151205-8

(51) Int. Cl. H02J 7/00

(52) U.S. Cl. CPC H02J 7/00719; H02J 7/00714; H02J 7/007182; H02J 7/007194

(57) ABSTRACT

The present invention relates to A NiMH battery charger (100) for charging a NiMH battery pack (101) with a plurality of NiMH battery cells (C1,C2,C3). The NiMH battery charger (100) comprises a converting unit (102) operable to receive an input voltage (Vin) and a control signal (D) and operable to generate a charge current (Iout) and/or a charge voltage (Vout) based on the input voltage (Vin) and the control signal (D). The NiMH battery charger (100) further comprises a measuring unit (103) operable to measure the charge voltage (Vout) and to measure the charge current (Iout), the measuring unit is further operable to measure a surface temperature (Text) of the NiMH battery pack with a temperature sensor (106). The NiMH battery charger (100) further comprises a controlling unit (104) operable to receive the measured charge voltage (Vout), the measured charge current (Iout), and the measured surface temperature (Text). The controlling unit is further operable to determine a gas partial pressure (px) by means of a physical battery model (300) and based on the measured surface temperature (Text), charge voltage (Vout), and charge current (Iout). The controlling unit (104) is further operable to generate the control signal (D) for controlling the converting unit (102) to generate the charge current (Iout) and/or the charge voltage (Vout) based on the determined gas partial pressure (px). The present invention also relates to a controlling method for a NiMH battery charger.

### TECHNICAL FIELD

The present disclosure relates to a NiMH battery charger. More particular, the invention relates to a NiMH battery charger that uses a physical battery model.

The present invention also relates to a control method of controlling the charge voltage in a NiMH battery charger.

### BACKGROUND

The NiMH battery is a well-known type of battery often used in applications where a prolonged lifetime is desired. The NiMH battery may be charged with different types of charging. The simplest type of charging involves charging with a fixed low current and a timer. For some long life applications, it is recommended to use C/30 or C/40 charging. There are two common charge methods, which are voltage limiting (VL) and current limiting (CL). In Ni-based batteries it is common to charge with a limited current (CL) and the voltage is allowed to fluctuate freely.

In a fast charger, the charge cycle must be terminated before overcharging occurs. A common method to detect when the NiMH battery is fully charged is to detect a small voltage drop over the terminals of the NiMH battery that occurs when the battery is fully charged. This small voltage drop proves to be very difficult to detect, which makes this method unreliable. Other methods uses for example detection of temperature change of the battery during charging. When the battery is not fully charged most of this energy is converted to chemical energy. However, when the cell reaches full charge, most of the charging energy is converted to heat. This increases the rate of change of battery temperature, which can be detected. Often combinations of dV/dt and dT/dt measurements are used in modern chargers together with a maximum defined voltage per cell and a maximum charging time. During charging a CL approach is often used until a condition of fully charged is detected then a CV approach may be used.

However, in a real battery pack it is often very difficult to detect a fully charged battery cell. Therefore, some battery cells often becomes overcharged and this is detrimental for a NiMH battery cell.

However, in order to improve charging various attempts have been performed to use physical models of the NiMH battery in order to improve charging. For example the article “Modelling of rechargeable NiMH batteries”, Journal of Alloys and compounds 356-357 (2003) 742-745, by Ledovskikh et al. discloses an attempt to model a NiMH battery during charging and overcharging. However, this model fails to describe discharging and aging. This model provides information about battery voltage, temperature and total internal pressure.

However, there is still a large need for an improved charging method for NiMH batteries that correctly assess the state of charge in all different modes of operation and for all states of aging in order to provide an optimum charging for the NiMH battery.

### SUMMARY

The present inventor has found that by employing a physical model of the NiMH battery that is valid in all states of operation an improved charging method may be identified. Especially, the partial gas pressure of the NiMH battery proves to be especially useful in devising a new charging method. By exploiting this finding, the inventor has devised a NiMH battery charger, and a control method.

An object of the present disclosure is to provide a an improved charging method for NiMH batteries and battery packs, which seeks to mitigate, alleviate, or eliminate one or more of the above-identified deficiencies in the art and disadvantages singly or in any combination and to provide an improved charging method. The present disclosure also relates to a NiMH battery charger.

According to the present invention there is provided a NiMH battery charger for charging a NiMH battery pack with a plurality of NiMH battery cells. The NiMH battery charger comprises a converting unit operable to receive an input voltage and a control signal and operable to generate a charge current and a charge voltage based on the input voltage and the control signal. The NiMH battery charger further comprises a measuring unit operable to measure the charge voltage and to measure the charge current. The measuring unit is further operable to measure a surface temperature of the NiMH battery pack with a temperature sensor. The NiMH battery charger further comprises a controlling unit operable to receive the measured charge voltage, the measured charge current, and the measured surface temperature. The controlling unit is further operable to determine a gas partial pressure by means of a physical battery model and based on the measured surface temperature, charge voltage, and charge current. The controlling unit is further operable to generate the control signal for controlling the converting unit to generate the charge current and/or the charge voltage based on the determined gas partial pressure.

According to one embodiment, the determined gas partial pressure is the partial pressure of oxygen and/or hydrogen.

According to one embodiment, the measuring unit is further operable to measure an internal pressure of the NiMH battery pack with a pressure sensor, and the controlling unit is operable to receive the measured pressure and base the determining of the gas partial pressure on the measured pressure in addition to the other measurements.

According to one embodiment, the pressure sensor is configured to be arranged in a common volume of all NiMH battery cells of the NiMH battery pack. This allows the use of a single pressure sensor in the NiMH battery pack.

According to one embodiment, the physical battery model comprises a mass balance module with expressions for hydrogen and oxygen, which are used to determine the phase distribution for the two electrodes by means of the measured current flowing from/to the NiMH battery. The physical battery model further comprises a voltage balance module operable to determine the positive electrode voltage based on a negative electrode voltage, the measured cell voltage and a cell resistance. The physical battery model further comprises an energy balance module with expressions, operable to determine a modeled internal temperature of the NiMH battery, the measured temperature is used to determine the heat transfer from the NiMH battery to the surroundings of the NiMH battery stack; and a gas pressure module with expressions for nitrogen, water vapor, hydrogen and oxygen, and operable to determine the partial gas pressure.

According to one embodiment, the physical battery model further comprises volume change expressions, electrode capacity equations, and expressions for aging.

According to one embodiment, the controlling unit generates a control signal that controls the converting unit to adjust the charging current and the charge voltage, upon detecting a gas partial pressure above a gas pressure threshold.

Moreover, the present invention also provides a control method of a NiMH battery charger. The NiMH battery charger comprises a converting unit, a measuring unit, and a controlling unit. The method comprises converting an input voltage to a charge voltage using a converting unit, measuring the charge voltage, measuring the charge current, measuring a surface temperature of the NiMH battery pack. The method further comprises determining a gas partial pressure by means of a physical battery model, the measured surface temperature, charge voltage, and charge current. The method further comprises generating a control signal for controlling the converting unit to generate the charge current and/or the charge voltage based on the determined gas partial pressure, and generating a charge voltage in dependence upon the control signal.

According to one embodiment, the determined gas partial pressure is the partial pressure of oxygen and/or hydrogen.

According to one embodiment, the control method further comprises measuring an internal pressure of the NiMH battery pack with a pressure sensor, and base the determining of the gas partial pressure on the measured pressure in addition to the other measurements.

According to one embodiment, the pressure sensor is configured to be arranged in a common volume of the NiMH battery cells of the NiMH battery pack.

According to one embodiment, the step of determining a partial gas pressure comprises determining the phase distribution for the two electrodes based on the measured current flowing from/to the NiMH battery, using a mass balance module with expressions for hydrogen and oxygen. The step of determining a partial gas pressure further comprises determining the positive electrode voltage based on a negative electrode voltage, the measured cell voltage and a cell resistance using a voltage balance module. The step of determining a partial gas pressure further comprises determining a modeled internal temperature of the NiMH battery, wherein the measured temperature is used to determine the heat transfer from the NiMH battery to the surroundings of the NiMH battery stack using an energy balance module. The step of determining a partial gas pressure further comprises determining the partial gas pressure using a gas pressure module with expressions for nitrogen, water vapor, hydrogen and oxygen.

According to one embodiment, the determining of a partial gas pressure further comprises determining volume change, electrode capacity, and aging of the NiMH battery pack.

According to one embodiment, the step of generating a control signal for controlling the converting unit further comprises adjusting the control signal so that the charging voltage is adjusted, upon detecting a gas partial pressure above a gas pressure threshold. This way a safe and optimum charging is achieved.

Further objects and advantages may be found in the detailed description.

### BRIEF DESCRIPTION OF THE DRAWINGS

The foregoing will be apparent from the following more particular description of the example embodiments, as illustrated in the accompanying drawings in which like reference characters refer to the same parts throughout the different views. The drawings are not necessarily to scale, emphasis instead being placed upon illustrating the example embodiments.

FIG. 1 is a block diagram illustrating embodiments of a NiMH battery charger according to the present invention.

FIG. 2 is a flow chart illustrating embodiments of method steps for a control method of controlling the charge voltage in a NiMH battery charger according to the present invention.

FIG. 3 is a block diagram illustrating embodiments of a physical model of a NiMH battery according to embodiments of the present invention.

### DETAILED DESCRIPTION

Aspects of the present disclosure will be described more fully hereinafter with reference to the accompanying drawings. The apparatus and method disclosed herein can, however, be realized in many different forms and should not be construed as being limited to the aspects set forth herein. Like numbers in the drawings refer to like elements throughout.

The terminology used herein is for the purpose of describing particular aspects of the disclosure only, and is not intended to limit the invention. As used herein, the singular forms “a”, “an” and “the” are intended to include the plural forms as well, unless the context clearly indicates otherwise.

Some of the example embodiments presented herein are directed towards an improved NiMH battery charger, and a control method. As part of the development of the example embodiments presented herein, a problem will first be identified and discussed. In conventional NiMH battery chargers, and especially in chargers for fast charging, it is critical to abort the charging cycle in order to avoid overcharging which may be detrimental for a NiMH battery.

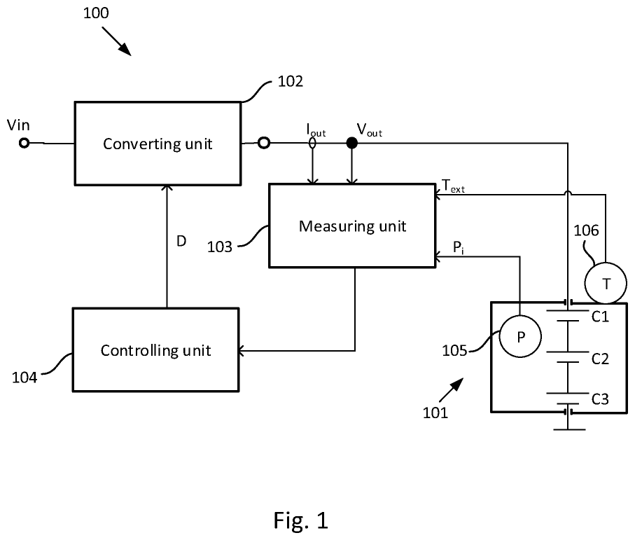

FIG. 1 shows a NiMH battery charger, generally designated 100, for charging a NiMH battery pack 101 with a plurality of NiMH battery cells C1, C2, C3. The NiMH battery charger 100 comprises:

A converting unit 102 operable to receive an input voltage Vin and a control signal D and operable to generate a charge current Iout and/or a charge voltage Vout based on the input voltage Vin and the control signal D.

A measuring unit 103 operable to measure the charge voltage Vout and to measure the charge current Iout, the measuring unit is further operable to measure a surface temperature Text of the NiMH battery pack with a temperature sensor 106.

A controlling unit 104 operable to receive the measured charge voltage Vout, the measured charge current Iout, and the measured surface temperature (Text). The controlling unit is further operable to determine a gas partial pressure px by means of a physical battery model 300 and based on the measured surface temperature Text, charge voltage Vout, and charge current (Iout). The controlling unit 104 is further operable to generate the control signal D for controlling the converting unit 102 to generate the charge current Iout and/or the charge voltage Vout based on the determined gas partial pressure px.

The determined gas partial pressure is the partial pressure of oxygen and/or hydrogen. The experimental results disclosed herein suggests that it is preferably to use the partial pressure of oxygen pO2 for charge controlling. However, it would also be possible to use the hydrogen partial pressure pH2 for the control, even if the oxygen partial pressure provides a more clear and defined signal.

Optionally, the measuring unit 103 is further operable to measure an internal pressure P of the NiMH battery pack 101 with a pressure sensor 105, and the controlling unit 103 is operable to receive the measured pressure P and base the determining of the gas partial pressure px on the measured pressure P in addition to the other measurements. The pressure sensor is a single common pressure sensor for all battery cells in the battery pack. This internal pressure P may be used for parameter extraction during the modeling of the NiMH battery.

The pressure sensor 105 is configured to be arranged in a common volume of all NiMH battery cells of the NiMH battery pack 101.

In one embodiment, each of the battery cells may have a dedicated pressure sensor arranged in each battery cell.

The converting unit 102 may be switched converter configured to convert the input voltage Vin to a lower, or higher, output voltage Vout for charging the battery pack 101. The converting unit may be configured for both constant current operation and constant voltage operation.

The controlling unit generates a control signal D that controls the converting unit to adjust the charging current Iout and the charge voltage Vout, upon detecting a gas partial pressure above a gas pressure threshold. This adjustment may comprise a change from a constant current charging scheme to a constant voltage scheme, if it is detected that the NiMH battery pack is fully charged.

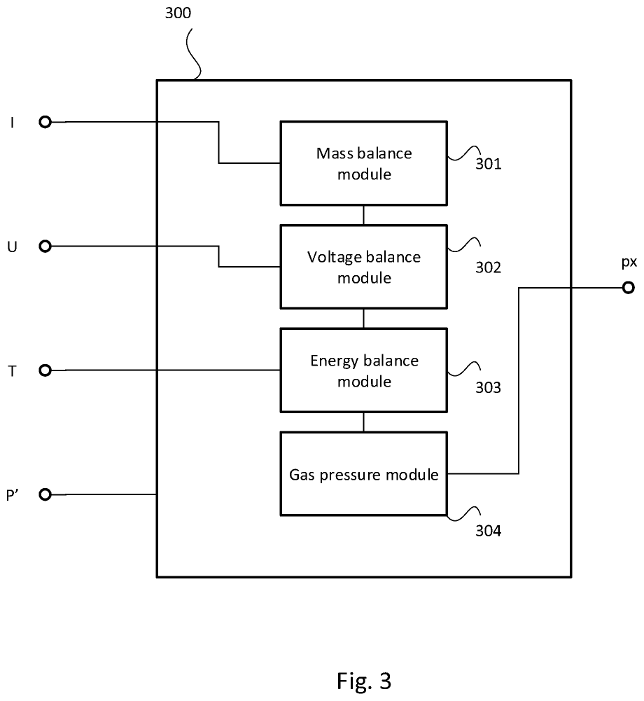

The present inventor has devised a new physical battery model with some beneficial advantages over known physical models for NiMH batteries. This new physical battery model is schematically illustrated in FIG. 3 and is generally designated 300. The physical battery model 300 comprises:

A mass balance module 301 with expressions for hydrogen and oxygen, which are used to determine the phase distribution for the two electrodes by means of the measured current Iout flowing from/to the NiMH battery.

A voltage balance module 302 operable to determine the positive electrode voltage based on a negative electrode voltage, the measured cell voltage and a cell resistance.

An energy balance module 303 with expressions, operable to determine a modeled internal temperature Tin of the NiMH battery, the measured temperature Text is used to determine the heat transfer from the NiMH battery to the surroundings of the NiMH battery stack, and A gas pressure module 304 with expressions for nitrogen, water vapor, hydrogen and oxygen, and operable to determine the partial gas pressure px.

Optionally, the physical battery model further comprises volume change expressions, electrode capacity equations, and expressions for aging.

The physical battery model will be presented in more detail herein below.

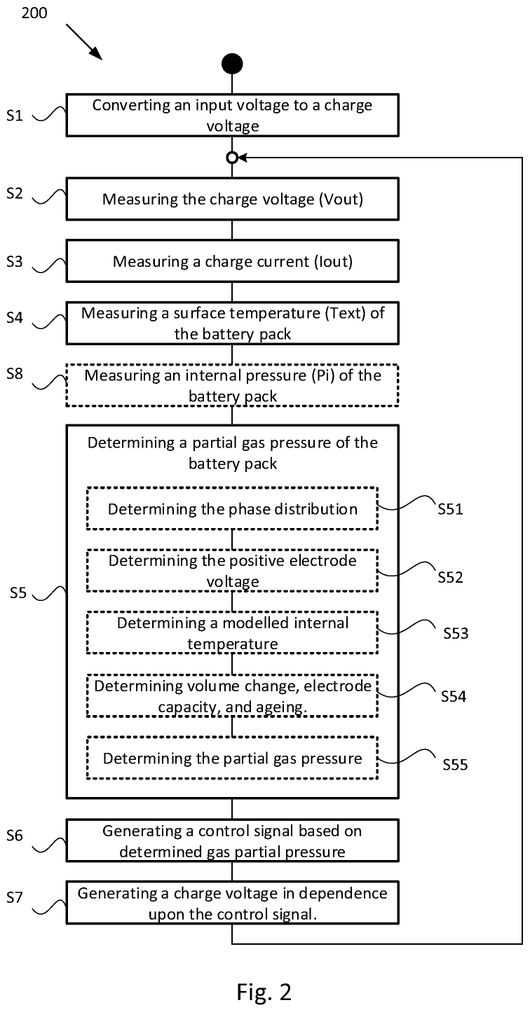

Now with reference made to FIG. 2 an embodiment of a control method of a NiMH battery charger will be disclosed.

A control method of a NiMH battery charger 100, wherein the NiMH battery charger comprises a converting unit 102, a measuring unit 103, and a controlling unit 104. The method 200 comprises:

Converting S1 an input voltage Vin to a charge current and/or a charge voltage Vout using a converting unit.

Measuring S2 the charge voltage Vout.

Measuring S3 the charge current Iout.

Measuring S4 a surface temperature Text of the NiMH battery pack.

Determining S5 a gas partial pressure px by means of a physical battery model 300 and based on the measured surface temperature Text, charge voltage Vout, and charge current Iout.

Generating S6 a control signal D for controlling the converting unit to generate the charge current Iout and/or the charge voltage Vout based on the determined gas partial pressure px, and

Generating S7 a charge current Iout and/or a charge voltage Vout in dependence upon the control signal D.

The determined gas partial pressure px is the partial pressure of oxygen and/or hydrogen.

Optionally, the control method, further comprises measuring S8 an internal pressure P of the NiMH battery pack with a pressure sensor, and base the determining S5 of the gas partial pressure px on the measured pressure P in addition to the other measurements (S2-S4).

The pressure sensor is configured to be arranged in a common volume of the NiMH battery cells of the NiMH battery pack.

Optionally, the step of determining S5 a partial gas pressure comprises:

Determining S51 the phase distribution for the two electrodes based on the measured current Iout flowing from/to the NiMH battery, using a mass balance module with expressions for hydrogen and oxygen.

Determining S52 the positive electrode voltage based on a negative electrode voltage, the measured cell voltage and a cell resistance using a voltage balance module.

Determining S53 a modeled internal temperature Tin of the NiMH battery, wherein the measured temperature Text is used to determine the heat transfer from the NiMH battery to the surroundings of the NiMH battery stack using an energy balance module.

Determining S55 the partial gas pressure px using a gas pressure module with expressions for nitrogen, water vapor, hydrogen and oxygen.

Optionally, the determining S5 of a partial gas pressure further comprises determining S54 volume change, electrode capacity, and aging of the NiMH battery pack.

Optionally, the step of generating S6 a control signal D for controlling the converting unit further comprises adjusting the control signal D so that the charging current Iout and/or the charging voltage Vout is adjusted, upon detecting a gas partial pressure above a gas pressure threshold.

In the following, the new physical gas model will be presented with reference made to FIG. 3.

To describe the NiMH battery, a OD model based on the physical and electrochemical processes taking place in the battery is constructed. There are four different dependent variables in the model: T, n_{H}_{₂}, n_{O}_{₂} and xₚₒₛ.

The pressure model is built around experimental data. The reason for this is that NiMH batteries have a significant hysteresis effect on the open-circuit-voltage, OCV, of the positive electrode. In any type of model for dynamic use that estimates the voltage, this hysteresis effect needs to be accounted for. By using the experimental cell voltage instead, the need to simulate the positive electrode voltage and avoid the hysteresis problem can be bypassed altogether. When subtracting the modeled negative electrode voltage from the experimental cell voltage, the positive electrode voltage is obtained, which represents E_{OCV}+η_{act}. This can then be used to calculate the oxygen evolution, which is potential dependent. Three sets of data are used to supply a base to estimate the composition of the battery gas phase. The battery current, I_{cell}; the module surface temperature, Tₑₓₚ; and the cell voltage, E_{cell}. The current is used to estimate the phase conversion and side reactions in the battery. The module surface temperature (Text) is used as an input to model the heat transfer from the module core to the surface. Finally, the experimental cell voltage is used to find the positive electrode voltage.

After setting up the model, the experimental pressure is used as comparison to the model generated pressure to fit the parameters using a Nelder-Mead optimization solver.

### [Mass Balance Module 301]

The gas composition in the battery is dependent on the overall species composition in the battery as well as the phase composition of the electrodes. Therefore, the model is based on a series of mass balances.

To track the electrochemical consumption and production of species, the electrode current composition is modeled. Electrode currents are connected to the reactions occurring on the electrode, with the total sum of the reaction currents equaling the cell current. On the negative electrode, there are two reactions: The charge reaction and the recombination of oxygen gives the following current balance:

$${I}_{c e l l} = - {I}_{M H} - {I}_{{O}_{2}}^{n e g} \qquad 1$$

Which gives the charge current from the total cell current and the oxygen recombination current. The recombination current is given by an Arrhenius expression, with a fitted rate constant, K_{O2}, and the activation energy:

$${I}_{{O}_{2}}^{n e g} = {K}_{{O}_{2}} * {p}_{{O}_{2}} * {e}^{\frac{- {E}_{D {O}_{2}}^{a}}{R} ( \frac{1}{T} - \frac{1}{{T}_{0}} )} \qquad 2$$

To make the equilibrium constant temperature dependent where a standard Arrhenius equation is used, a reference temperature is needed. It's chosen to be the initial temperature: T₀=T^{init}.

The positive electrode current distribution is determined by three competing reactions: The charge/discharge reaction, the oxygen evolution reaction, and the Hydrogen oxidation reaction. This gives us the following current balance:

$${I}_{c e l l} = {I}_{N i O O H} + {I}_{{O}_{2}}^{p o s} + {I}_{{H}_{2}}^{p o s} \qquad 3$$

To estimate the oxygen production current, we first need an overpotential vs. the equilibrium voltage. This over potential is found by comparing the equilibrium potential for oxygen evolution at the pH of the electrolyte, E⁰_{O2}, to the positive electrode voltage according to Equation η_{O}_{₂}=Eₚₒₛ−E [symbol] O₂O14, which is described in the next section. This in turn is used together with experimental data from Ayeb et al., who investigated the oxygen evolution kinetics in the NiMH system [16]. They study the reaction mechanism and kinetics and conclude that there are two different kinetic relationships: one for the partially charged Ni(OH)₂ electrode and one for the overcharging region. To make this model work in dynamic conditions we have combined these two empirical relationships so that the relationship for the partial charging is used for lower potentials, and when reaching higher potentials, the overcharge relationship is used. In this model, the two relationships are combined into one. The exchange current density is dependent on both overpotential and temperature. The oxygen evolution current is then found using the following relationship, where k_{OER} is a fitted parameter:

$${I}_{{O}_{2}}^{p o s} = {k}_{O E R} * {e}^{{I}_{OER}^{tafel}}$$

The hydrogen current is given by the assumption that any hydrogen that manages to reach the positive electrode surface has no kinetic limitation due to the high potential. It is therefore limited by the mass transport from the gaseous bulk to the electrode surface. For this we use an Arrhenius expression, with the hydrogen pressure in the gaseous bulk as a driving force and with a fitting parameter K_{H}_{₂}^{pos} that serves as a combined reaction coefficient and mass transfer coefficient. E_{DH}_{₂}^{a}, is taken from Albertus et al [10]. As in the case with the previous Arrhenius equation, T₀=T^{init}.

$${I}_{{H}_{2}}^{p o s} = {K}_{{H}_{2}}^{p o s} * {p}_{{H}_{2}} * {e}^{\frac{- {E}_{D {H}_{2}}^{a}}{R} ( \frac{1}{T} - \frac{1}{{T}_{0}} )}$$

The electrode currents can then be used to keep track of the molar amounts of hydrogen and oxygen present in the battery through the establishment of molar balances. The oxygen amount present in the battery is modeled using a differential expression:

$$\frac{{dn}_{{O}_{2}}}{dt} = \frac{{I}_{{O}_{2}}^{pos} + {I}_{{O}_{2}}^{neg}}{4 F} \qquad 4$$

$$with {n}_{{O}_{2}}^{init} = \frac{{p}_{{O}_{2}}^{init} {V}_{g a s}^{init}}{R {T}^{init}} .$$

Here, as no oxygen intercalation is made and little gas is solved in the electrolyte due to the starved configuration of the battery, all oxygen is assumed to be in the gas phase. As oxygen is recombined swiftly at the negative electrode and the battery is at rest at the beginning of the experiments, the initial oxygen pressure is assumed to be close to zero with p_{O}_{₂}^{init}=0.001 atm.

As for hydrogen, the hydrogen present in the battery is also modeled using a differential expression:

$$\frac{{dn}_{{H}_{2}}}{dt} = \frac{{I}_{{H}_{2}}^{p o s} + {I}_{M H}}{2 F} \qquad 5$$

$$With {n}_{{H}_{2}}^{init} = \frac{{x}_{n e g}^{init} {q}_{n e g}}{2 F} .$$

Since the hydrogen in the battery can be found both in the gas phase and in the negative electrode, the distribution is a bit more complex than for oxygen. However, in the case of this battery n_{H}_{₂}^{(g)}<<n_{MH}, which makes it possible to simplify the expression so that all hydrogen in the total mole balance is intercalated in the electrode:

$${n}_{{H}_{2}} = 2 {n}_{M H} \qquad 6$$

Once the total mass balances have been established, the phase distribution expressions for the two electrodes can be formulated. For the negative electrode, we use the calculated molar amount of hydrogen to calculate the degree of intercalation:

$${x}_{n e g} = \frac{{n}_{M H} F}{{q}_{n e g}} \qquad 7$$

Where x_{neg}=1 is fully charged and x_{neg}=0 is fully discharged.

On the positive electrode all the charge current results in intercalation, and we arrive at the following expression:

$$\frac{{dx}_{p o s}}{dt} = - \frac{{J}_{NiOOH}}{{q}_{p o s}} \qquad 8$$

Where xₚₒₛ=0 is fully charged and xₚₒₛ=1 is fully discharged. As the positive electrode fraction is one of the most predictable variables, two positive electrode fractions at determined test times are used to bind the model to a reasonable solution: The beginning of discharge (t^{BoD}, xₚₒₛ^{BoD}); and the end of discharge (t^{EoD}, xₚₒₛ^{EoD}).

While the degree of intercalation in the positive electrode is straight forward, the phase distribution is more complex. The discharged electrode is assumed to consist of β-Ni(OH)₂, which is then transformed to β-NiOOH as the electrode is charged according to the classic article by Bode et al. However, unlike the traditional Bode diagram it has been found that the charged material can exist in more than the β-NiOOH phase. [19] When charged, the β-Ni(OH)₂ loses a hydrogen and a TP2 NiOOH-phase, with a similar unit cell, is produced. The kinetically favored TP2 NiOOH-phase can then collapse into a more thermodynamically favored phase, β-NiOOH, with a smaller unit cell. The fraction of the electrode present in the β-NiOOH phase is assumed to be in equilibrium with the TP2 NiOOH-phase and dependent on the electrode voltage. As such, it is modeled with an exponential expression using two fitted constants—A_{β} & B_{β}, the positive electrode potential, and the charge fraction of the electrode.

$${x}_{β} = ( 1 - {x}_{p o s} ) {A}_{β} * {e}^{- {B}_{β} {E}_{p o s}} \qquad 9$$

The positive electrode voltage is used on the assumption that the voltage behavior of the positive electrode is related to the phase of the material.

### [Voltage Balance Module 302]

The positive electrode voltage can be estimated using the negative electrode voltage, the cell voltage, and the cell resistance according to the following expression:

$${E}_{c e l l} = {E}_{p o s} - {E}_{n e g} + {I}_{c e l l} {R}_{Ω} \qquad 10$$

Where R_{Ω} is an experimentally determined resistance that depends on the state of charge of the positive electrode.

The negative electrode voltage was calculated using the Pressure Composite Isotherm (PCT) curve of the material. This curve plots the equilibrium pressure over the metal hydride as a function of hydrogen content. By keeping track of the hydrogen content in the electrode, the corresponding equilibrium pressure can be used for the hydrogen pressure dependent model expressions. The PCT is given at a certain temperature, so we use the Van't Hoff relation to adjust the temperature of the PCT curve. [20]

$$ln {p}_{{H}_{2}} = \frac{Δ {S}_{MH}^{∘}}{R} ( 1 - \frac{{T}_{ref}}{T} ) + \frac{{T}_{r e f}}{T} ln {p}_{{H}_{2}}^{P C T} \qquad 11$$

Where T_{ref} is the temperature used when recording the PCT curve, and p_{H}_{₂}^{PCT} is the PCT hydrogen pressure. The Nernst equation, assuming γ=1 and a_{H}_{₂}_{O}=1, gives the following expression for E_{MH}: [14]

$${E}_{M H} = {E}_{MH}^{∘} - \frac{R T}{2 F} ln ( \frac{{p}_{{H}_{2}}}{{p}_{{H}_{2}}^{∘}} ) \qquad 12$$

Where we used the E°_{MH} given by Kleperis et al. [21]

Adding an overpotential expression for the negative electrode had limited contribution to the model, resulting in the following simplified expression for the negative electrode:

$${E}_{n e g} = {E}_{M H} \qquad 13$$

From the positive electrode potential, one can further calculate the oxygen evolution overpotential, which is needed to estimate the oxygen evolution reaction rate. The oxygen evolution overpotential is given by the following expression:

$${η}_{{O}_{2}} = {E}_{p o s} - {E}_{{O}_{2}}^{0} \qquad 14$$

Where E_{O}_{₂}⁰, is the equilibrium potential for oxygen evolution.

### [Energy Balance Module 303]

To find the model temperature, energy balance expressions are introduced. The model uses a modeled, internal temperature, T, which is calculated using the following ODE:

$$\frac{dT}{dt} = \frac{1}{{V}_{Cp}} ( {Q}_{Ω} + {Q}_{{O}_{2}} + {Q}_{M H} + {Q}_{N i O O H} + {Q}_{{H}_{2}} + {Q}_{{H}_{2} O}^{vap} - {Q}_{{H}_{2}}^{vap} - {Q}_{H T} ) \qquad 15$$

The battery is assumed to be at an even temperature when the experiment is started, and so the initial modeling temperature is equal to the initial experimental temperature, T^{init}=Tₑₓₚ(0).

To model the heat from reactions, the thermoneutral voltage is used. As the thermoneutral voltage hasn't been experimentally determined, both the thermoneutral cell voltage and an offset factor for the negative charge/discharge reaction are fitted.

$${E}_{M H}^{therm} = {E}_{c e l l}^{therm} + {E}_{{H}_{2}}^{0} + {E}_{H M}^{thermoffset} \qquad 16$$

Once the thermoneutral voltage for the charge/discharge reaction on the negative electrode is obtained, the heat is calculated using the charge/discharge current and the voltage gap between the electrode voltage and the thermoneutral voltage:

$${Q}_{MH} = {I}_{M H} ( {E}_{n e g} - {E}_{M H}^{therm} ) \qquad 17$$

For the heat generation on the positive electrode the thermoneutral voltage is used in the same manner as for the negative electrode. For the positive electrode the following formula is used to calculate the thermoneutral voltage for the charge/discharge reaction:

$${E}_{N i O O H}^{therm} = {E}_{c e l l}^{therm} - {E}_{M H}^{therm} \qquad 18$$

The heat production is then calculated using the charge/discharge current and the difference between the positive electrode voltage and the thermoneutral voltage for the charge/discharge reaction:

$${Q}_{N i O O H} = {I}_{N i O O H} ( {E}_{p o s} - {E}_{N i O O H}^{therm} ) \qquad 19$$

Apart from the main charge reactions on the positive and negative electrode there are heat contributions terms from other processes as well: Side reactions, phase changes, IR heating and conduction.

As described above, hydrogen in the gas phase can travel to the positive electrode and become oxidized. The heat contribution from this process is calculated using the following expression, where the oxidation current is multiplied with the voltage difference between the positive electrode voltage and the thermoneutral hydrogen oxidation voltage E_{MH}:

$${Q}_{{H}_{2}} = {I}_{{H}_{2}}^{p o s} ( {E}_{p o s} - {E}_{M H}^{therm} ) \qquad 20$$

Similarly, oxygen plays an important part in the side reactions. It will first be produced on the positive electrode towards end of charge when the voltage rises, and then recombined on the negative electrode. Each of these two reactions will contribute to the oxygen production and recombination heat term, using the same method as for the hydrogen oxidation:

$${Q}_{{O}_{2}} = {I}_{{O}_{2}}^{p o s} ( {E}_{p o s} - {E}_{{O}_{2}}^{therm} ) + {I}_{{O}_{2}}^{n e g} ( {E}_{n e g} - {E}_{{O}_{2}}^{therm} ) \qquad 21$$

There is also heat generated by phase changes in the system. There are two different expressions for this, as both water and hydrogen undergo phase changes. The phase-change heat is given by the following reactions:

$${Q}_{{H}_{2} O}^{vap} = \frac{{dp}_{{H}_{2} O}}{dt} * \frac{{V}_{g a s}}{R T} Δ {H}_{vap , 25 ° C .}^{{H}_{2} O} \qquad 22$$

$${Q}_{{H}_{2}}^{v a p} = \frac{{dp}_{{H}_{2}}}{dt} * \frac{{V}_{g a s}}{R T} ( Δ {H}_{fus}^{{H}_{2}} + Δ {H}_{vap}^{{H}_{2}} ) \qquad 23$$

Regarding the IR heating source term, it is the heat produced due to the ohmic resistance of the battery. Joule's first law is used to calculate the heat contribution:

$${Q}_{Ω} = {R}_{Ω} {I}_{cell}^{2} \qquad 24$$

The final process is conductive heat transfer, which is driven by the temperature difference between the surface of the battery and the internal battery temperature. To find a driving force for conductive heat transfer, the experimental temperature is taken as the surface temperature of the battery.

$${T}_{surf} = {T}_{exp} \qquad 25$$

By using the experimental surface battery temperature, no knowledge of the ambient temperature is needed, something that makes modeling on-line in systems easier. The model temperature is regulated through fitting of the heat transfer constant, K_{T}, that determines the heat loss through conduction to the battery surface. The battery heat capacity, V_{cρ}, is also fitted. The energy balance below is used to estimate the heat transfer from the inside to the outside of the battery:

$${Q}_{HT} = {K}_{T} ( T - {T}_{surf} ) \qquad 26$$

### [Help Expressions]

Apart from the mass, voltage and energy balances other expressions may be needed for a optimum model. These are the volume change expressions and the electrode capacity equations that include both initial values and aging.

The free gas volume is of importance for this model, as it governs nitrogen and oxygen pressure. So therefore, we need to keep track of the volumes of the electrodes. This is done through using the unit cell parameters to calculate the electrode volume if the electrode consisted of a singular phase. This is done for the charged and discharged phases of the electrodes:

$${V}_{β} = {V}_{β}^{unit} * {q}_{pos} \qquad 27$$

$${V}_{{Ni ( OH )}_{2}} = {V}_{{Ni ( OH )}_{2}}^{unit} * {q}_{pos} \qquad 28$$

$${V}_{M} = {V}_{M}^{unit} * {q}_{neg} \qquad 29$$

$${V}_{MH} = {V}_{MH}^{unit} * {q}_{neg} \qquad 30$$

The unit cell volume is calculated using the unit cell dimensions. Considering that all phases are of the hexagonal type with an equilateral parallelogram base and a 60° angle, the following geometrical relationship was used:

$${V}^{unit} = c * {a}^{2} * sin 60 \qquad 31$$

Where the unit cell dimensions for the positive materials is from Oliva et al [22]. The unit cell dimensions for the negative electrode are taken from Willems et al [23]. The stored charge per cell was then used to calculate the volume per stored Ah.

Combining the expressions for total single phase electrode volumes with the molar fractions of the phases results in expressions for the electrode volumes:

$${V}_{pos} = {V}_{{Ni ( OH )}_{2}} ( 1 - {x}_{β} ) + {x}_{β} {V}_{β} \qquad 32$$

$${V}_{neg} = {x}_{neg} {V}_{MH} + ( 1 - {x}_{neg} ) {V}_{M} \qquad 33$$

With Vₚₒₛ^{init}=Vₚₒₛ(x_{β}^{init}) and V_{neg}^{init}=V_{neg}(x_{neg}^{init}). The gas volume can then be calculated from the following relationship:

$${V}_{tot} = {V}_{pos} + {V}_{neg} + {V}_{gas} \qquad 34$$

Which also gives us V_{gas}^{init}=Vₜₒₜ−Vₚₒₛ^{init}−V_{neg}^{init}. Vₜₒₜ is fitted to the data, as it is difficult to experimentally determining exactly what the total available volume is, but within a span that is reasonable judging from the dimensional parameters of the cell. This Vₜₒₜ only includes the gas volume and the volume of the active material, not electrolyte volume, separator volume or the volume of any carrier materials.

The battery is designed with positive limiting capacity, with a negative electrode that has a significantly larger capacity than the positive. This means that each electrode has its own capacity and intercalation expression. When initializing the model, it is important that the model is at the same electrode charge levels as the battery, which in the model is represented by the electrode intercalation fractions. The most predictable state is when the battery is fully discharged, which is where the experimental data in this study begins. That lets us put xₚₒₛ=1, but the initial intercalation in the negative electrode is more complex.

The intercalation of the negative electrode is the opposite of positive, so that when the electrode is fully discharged x_{neg}=0, and when the electrode is fully charged x_{neg}=1. However, it is not possible to initiate the model at x_{neg}=0 since the electrodes do not match up at fully discharged. This is due to a part of the battery manufacturing processes called the formation, where the battery goes through a string of processes designed to let the battery mature chemically to its functioning state. In the case of the NiMH battery, hydrogen is produced during this process which is then intercalated into the negative electrode. This creates a hydrogen buffer which is commonly called the over-discharge reserve, q_{OD}, and that can be calculated from the ingoing composition of the positive electrode materials. The over-discharge capacity turns into an intercalation fraction using the following relationship:

$${x}_{OD} = \frac{{q}_{OD}}{{q}_{neg}} \qquad 35$$

When initializing the model, the negative electrode intercalation faction can then be found through the following relationship:

$${x}_{neg}^{init} = \frac{{q}_{pos}}{{q}_{neg}} * ( 1 - {x}_{pos}^{init} ) + {x}_{OD} \qquad 36$$

When the battery ages, there is a need to add to these initial expressions to decide the negative electrode initial fraction and capacity. Since oxidation of the negative is the major aging mechanism of the NiMH battery, any aging will cause shifting of the electrode balances. This, in turn, has consequences for the hydrogen pressure in the cell. Aging affects the capacity of the negative electrode in two ways: The corroded material can no longer intercalate hydrogen, and so the total capacity is lowered; and the corrosion process produces hydrogen that is then intercalated into the negative electrode, increasing the over-discharge reserve. Leblanc et al. estimated this extra MH occupancy to 1.15 for each corroded site. This leads to the introduction of a constant, k_{corr}, to the model, which is fitted. This constant will promote a better description of battery age into account.

$${q}_{neg} = {q}_{neg}^{new} ( 1 - {k}_{corr} ) \qquad 37$$

$${q}_{OD} = {q}_{OD}^{new} + 1.15 {k}_{corr} {q}_{neg}^{new} \qquad 38$$

### [Gas Pressure Module 304]

Finally, once all of the previous equations have been set up for the system everything that is needed to set up the expressions for the cell pressure is in place. The pressure in the cell is given by four different gases: Nitrogen, water vapor, hydrogen, and oxygen. The first gas, Nitrogen, is present due to how the battery is manufactured. As the battery is filled with electrolyte air fills up the remaining empty volume. The amount of nitrogen in the cell is consistent over the cycles, but the pressure will vary with temperature and free gas volume. We have chosen to use the ideal gas law to track the nitrogen pressure over the charge/discharge cycle starting from the initial nitrogen pressure:

$${p}_{{N}_{2}}^{init} = {p}_{exp} ( 0 ) - {p}_{{H}_{2} O}^{init} - {p}_{{H}_{2}}^{init} - {p}_{{O}_{2}}^{init} \qquad 39$$

$${p}_{{N}_{2}} = {p}_{{N}_{2}}^{init} \frac{{TV}_{gas}^{init}}{{T}^{init} {V}_{gas}} \qquad 40$$

Second there is water present in the cell, which means that there will be water present in the gas phase. The water pressure in bar is calculated using an steam pressure equation adjusted for the hydroxide concentration, something that is necessary as the electrolyte is highly concentrate. The pressure is given in bar and the temperature in K.

$${log}_{10} {p}_{{H}_{2} O} = - 0.01508 {c}_{KOH} - 0.0016788 {c}_{OH}^{2} + 2.25887 * {10}^{- 5} {c}_{OH}^{3} + ( 1 - 0.0012062 {c}_{OH} + 5.6024 * {10}^{- 4} {c}_{OH}^{2} - 7.8228 * {10}^{- 6} {c}_{OH}^{3} ) \text{} ( 35.4462 - \frac{3343.93}{T} - 10.9 * {log}_{10} T + 0.0041645 T ) \qquad 41$$

$$With {p}_{{H}_{2} O}^{init} = {p}_{{H}_{2} O} ( {T}^{init} ) .$$

Hydrogen pressure has already been defined and is given by equation ln

$${p}_{{H}_{2}} = \frac{Δ {S}_{MH}^{°}}{R} ( 1 - \frac{{T}_{ref}}{T} ) + \frac{{T}_{ref}}{T} ln {p}_{{H}_{2}}^{PCT} \qquad 11$$

$$with {p}_{{H}_{2}}^{init} = {p}_{{H}_{2}} ( {T}^{init} , {x}_{neg}^{init} ) .$$

pH2=ΔSMH°R1−TrefT+TrefT ln pH2PCT 11

Finally, we have the oxygen pressure which is developed as the battery nears the end of charge. The oxygen pressure is given as a function of the ideal gas law and the molar amount of oxygen present in the cell.

$${p}_{{O}_{2}} = {n}_{{O}_{2}} \frac{RT}{{V}_{gas}} \qquad 42$$

In all, the total pressure in the cell is given by:

$${p}_{tot} = {p}_{{N}_{2}} + {p}_{{H}_{2} O} + {p}_{{H}_{2}} + {p}_{{O}_{2}} \qquad 43$$

In the drawings and specification, there have been disclosed exemplary embodiments. However, many variations and modifications can be made to these embodiments. Accordingly, although specific terms are employed, they are used in a generic and descriptive sense only and not for purposes of limitation, the scope of the embodiments being defined by the following claims.

The description of the example embodiments provided herein have been presented for purposes of illustration. The description is not intended to be exhaustive or to limit example embodiments to the precise form disclosed, and modifications and variations are possible in light of the above teachings or may be acquired from practice of various alternatives to the provided embodiments. The examples discussed herein were chosen and described in order to explain the principles and the nature of various example embodiments and its practical application to enable one skilled in the art to utilize the example embodiments in various manners and with various modifications as are suited to the particular use contemplated. The features of the embodiments described herein may be combined in all possible combinations of methods, apparatus, modules, systems, and computer program products.

It should be appreciated that the example embodiments presented herein may be practiced in any combination with each other. It should be noted that the word “comprising” does not necessarily exclude the presence of other elements or steps than those listed and the words “a” or “an” preceding an element do not exclude the presence of a plurality of such elements. It should further be noted that any reference signs do not limit the scope of the claims, that the example embodiments may be implemented at least in part by means of both hardware and software, and that several “means”, “units” or “devices” may be represented by the same item of hardware.

In the drawings and specification, there have been disclosed exemplary embodiments. However, many variations and modifications can be made to these embodiments. Accordingly, although specific terms are employed, they are used in a generic and descriptive sense only and not for purposes of limitation, the scope of the embodiments being defined by the following claims.

1. A NiMH battery charger for charging a NiMH battery pack with a plurality of NiMH battery cells (C1,C2,C3), the NiMH battery charger comprising:
a converting unit operable to receive an input voltage (Vin) and a control signal (D) and operable to generate a charge current (Iout) and/or a charge voltage (Vout) based on the input voltage (Vin) and the control signal (D);
a measuring unit operable to measure the charge voltage (Vout) and to measure the charge current (Iout), the measuring unit being further operable to measure a surface temperature (Text) of the NiMH battery pack with a temperature sensor;
a controlling unit operable to receive the measured charge voltage (Vout), the measured charge current (Iout), and the measured surface temperature (Text), the controlling unit being further operable to determine a gas partial pressure (px) using a physical battery model and based on the measured surface temperature (Text), the measured charge voltage (Vout), and the measured charge current (Iout), the controlling unit (104) being further operable to generate the control signal (D) for controlling the converting unit to generate the charge current (Iout) and/or the charge voltage (Vout) based on the determined gas partial pressure (px).

2. The NiMH battery charger according to claim 1, wherein the determined gas partial pressure is the partial pressure of oxygen and/or hydrogen.

3. The NiMH battery charger according to claim 1, wherein the measuring unit is further operable to measure an internal pressure (P) of the NiMH battery pack with a pressure sensor; and
wherein the controlling unit is operable to receive the measured pressure (P) and base the determining of the gas partial pressure (px) on the measured pressure (P).

4. The NiMH battery charger according to claim 5, wherein the pressure sensor is configured to be arranged in a common volume of all NiMH battery cells of the NiMH battery pack.

5. The NiMH battery charger according to claim 1, wherein the physical battery model comprises:
a mass balance module with expressions for hydrogen and oxygen, which are used to determine a phase distribution for the two electrodes using the measured current (Iout) flowing from/to the NiMH battery pack;
a voltage balance module operable to determine a positive electrode voltage based on a negative electrode voltage, a measured cell voltage and a cell resistance;
an energy balance module with expressions, operable to determine a modeled internal temperature (Tin) of the NiMH battery pack, wherein the measured surface temperature (Text) is used to determine heat transfer from the NiMH battery pack to the surroundings of the NiMH battery pack; and
a gas pressure module with expressions for nitrogen, water vapor, hydrogen and oxygen, and operable to determine the gas partial pressure (px).

6. The NiMH battery charger according to claim 1, wherein the physical battery model further comprises:
volume change expressions;
electrode capacity equations; and
expressions for aging.

7. The NiMH battery charger according to claim 1, wherein the controlling unit generates the control signal (D) that controls the converting unit to adjust the charging current (Iout) and the charge voltage (Vout), upon detecting a gas partial pressure above a gas pressure threshold.

8. A control method of a NiMH battery charger for charging a NiMH battery pack, wherein the NiMH battery charger includes a converting unit, a measuring unit, and a controlling unit, the method comprising:
converting an input voltage (Vin) to a charge current (Iout) and/or a charge voltage (Vout) using the converting unit;
measuring the charge voltage (Vout);
measuring the charge current (Iout);
measuring a surface temperature (Text) of the NiMH battery pack;
determining a gas partial pressure (px) using a physical battery model and based on the measured surface temperature (Text), the measured charge voltage (Vout), and the measured charge current (Iout);
generating a control signal (D) for controlling the converting unit to generate the charge current (Iout) and/or the charge voltage (Vout) based on the determined gas partial pressure (px); and
generating the charge current (Iout) and/or the charge voltage (Vout) in dependence upon the control signal (D).

9. The control method according to claim 8, wherein the determined gas partial pressure (px) is the partial pressure of oxygen and/or hydrogen.

10. The control method according to claim 8, further comprising measuring an internal pressure (P) of the NiMH battery pack with a pressure sensor;
wherein determining the gas partial pressure (px) is based on the measured pressure (P).

11. The control method according to claim 10, wherein the pressure sensor is configured to be arranged in a common volume of NiMH battery cells of the NiMH battery pack.

12. The control method according to claim 8, wherein determining a partial gas pressure comprises:
determining a phase distribution for the two electrodes based on the measured charge current (Iout) flowing from/to the NiMH battery pack, using a mass balance module with expressions for hydrogen and oxygen;
determining a positive electrode voltage based on a negative electrode voltage, a measured cell voltage and a cell resistance using a voltage balance module;
determining a modeled internal temperature (Tin) of the NiMH battery pack, wherein the measured surface temperature (Text) is used to determine the heat transfer from the NiMH battery pack to the surroundings of the NiMH battery pack using an energy balance module;
determining the partial gas pressure (px) using a gas pressure module with expressions for nitrogen, water vapor, hydrogen and oxygen.

13. The control method according to claim 12, wherein the determining of the partial gas pressure further comprises:
determining volume change, electrode capacity, and aging of the NiMH battery pack.

14. The control method according claim 8, wherein generating the control signal (D) for controlling the converting unit further comprises adjusting the control signal (D) so that the charging current (Iout) and/or the charging voltage (Vout) is adjusted, upon detecting a gas partial pressure above a gas pressure threshold.
